(19) United States
(12) Patent Application Publication
(10) Pub. No.: US 2009/0267631 A1
(43) Pub. Date: Oct. 29, 2009

(54) Large Component Thermal Head Adapter

(75) Inventors: Terry R. Earle, Kenneth City, FL (US); Timothy Pursel, Land O Lakes, FL (US); Lance LeRoy Sundstrom, Pinellas Park, FL (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 12/108,970

(22) Filed: Apr. 24, 2008

(51) Int. Cl. G01R 31/02

(52) U.S. Cl. 324/760

(57) ABSTRACT

A thermal head adapter for testing a device under test is provided that can accommodate a large device and will improve the airflow through the thermal head to the device under test and out into the shroud. The thermal head adapter comprises a first section with a first perimeter and a second section with a second perimeter. The shroud is sealed onto an upper surface of first section, and the base of the second section attaches to a printed board. The perimeter of the first section is greater than the perimeter of the second section. The upper surface of the first section may comprise ridges that effectively form a moat-like structure to capture fallen condensation from the shroud walls. A drain may take the liquid within the boundary of the ridges to a desired location outside of the thermal head adapter.

### GOVERNMENT RIGHTS

This invention was made with Government support under Prime Contract Number N00030-05-C-0007 awarded by the United States Navy. The Government may have certain rights in this invention.

### FIELD

The present invention relates generally to thermal testing of a device under test. More particularly, the present invention relates to a thermal head adapter used with a precision temperature forcing system.

### BACKGROUND

A precision temperature forcing system (PTFS) provides a low-cost means to thermally test a device under test (DUT). The thermal head of a PTFS is designed for coplanar positioning of the bottom edges of its thermal cap and glass shroud. This usually involves pressure sealing the bottom edges of the thermal cap and shroud directly to the host printed board (PB) of the DUT. A compressible gasket allows for the thermal cap and shroud to seal against the PB. The air nozzle is retractable against a spring for sealing the bottom edge of the thermal cap to the PB.

The thermal cap is attached to the air flow nozzle of the PTFS thermal head and directs temperature controlled air directly onto the DUT and then out through its vent holes into the shroud area. The thermal cap is intended to direct air flow onto the DUT and minimize the air volume directly around the DUT, reducing the air flow rate necessary to force the DUT to the target temperatures.

However, standard conductive or nonconductive silicone rubber thermal caps accommodate only a limited range of component sizes, wherein the component is a direct-mounted DUT or a DUT mounted in a test socket. When a DUT or its test socket is too large to fit inside a standard thermal cap, or the thermal cap cannot be retracted far enough to seal to the top of the DUT or its test socket, the thermal cap can be omitted. However, once the thermal cap is omitted the entire shroud air volume must be forced to the target temperatures. The extra thermal load slows down temperature transition times and also requires higher air flow rates, which can cause condensation and icing issues at extended cold temperatures.

In an attempt to solve this problem, the PB area around the large test socket is built up using a material such as electrostatic discharge (ESD) foam to raise the shroud footprint up to the top of the test socket. With this configuration, the thermal cap can seal to the top the test socket. However, only a small portion of the DUT body surface is exposed to the forced air, resulting in a rather poor thermal transfer between the forced air and the DUT. Additionally, this built-up footprint requires a large “keep out” area around the DUT so that the ESD foam may properly seal to both the thermal head shroud and host PB.

Finding a material suitable for adapting to a larger than standard DUT is also problematic. The material must be pliable and compressible to provide a good air seal. Conductive and nonconductive silicone foam rubber sheets are compatible with the temperature ranges but they are very expensive and the nonconductive foam presents electrostatic discharge (ESD) issues. Either conductive silicone foam rubber or standard electrostatic discharge foam can cause electrical leakage currents across exposed PB surface solder pads and circuit traces. Typical standard electrostatic discharge foam, however, has a tendency to deform, shrink and become brittle with multiple temperature cycles. This leads to air leakage which can result in condensation and icing issues. Characterization and production testing requires a durable and reliable solution for thermal testing a DUT or a test socket containing a DUT that is larger than standard thermal cap sizes. This is especially challenging when a DUT must be tested over a wide temperature range (e.g. −55° C. to +125° C.).

### SUMMARY

In accordance with the present invention, a thermal head adapter for testing a device under test (DUT) is provided. This thermal head adapter can accommodate a large DUT or a test socket containing a DUT and will improve durability and reliability for thermally testing a large DUT or a DUT test socket while requiring a much smaller printed board (PB) footprint.

The thermal head adapter interfaces the PB to the shroud. The thermal head adapter comprises a first section with a first substantially circular perimeter and a second section with a second perimeter. The shroud is pressure sealed onto an upper surface of first section, and the base of the second section is pressure sealed to the PB. The perimeter of the first section is greater than the perimeter of the second section. The upper surface of the first section may comprise ridges that effectively form a substantially circular moat-like structure to capture fallen condensation from the shroud walls. A drain may take the liquid within the boundary of the ridges to a desired location outside of the thermal head adapter. A nitrogen port may be located within the first section and may carry dry nitrogen gas from an outside source into the shroud. The thermal head adapter has a cavity that runs through both the first section and the second section, allowing for the placement of the thermal head adapter over a DUT or a DUT test socket. Flexible foil heaters with integral temperature sensors may be bonded to the exterior of the base near the PB interface and to the exterior opposite the thermal head shroud footprint. The heaters maintain the surface temperature of the thermal head adapter above the dew point to prevent condensation from moist room air.

This thermal head adapter allows for all forced air to flow down through the precision temperature forcing system's air nozzle and thermal cap, and go directly onto the DUT or the exposed portion of the DUT in a test socket, out the thermal cap vent holes and into the shroud area. This minimizes the thermal load required to force the DUT to the proper temperature, since the thermal cap no longer needs to be omitted for a larger than standard DUT or a DUT test socket. The additional advantages associated with this are improved reliability and reduction of cost and schedule associated with DUT temperature testing. Without condensation and icing issues, long thermal cycles can be automated and unmanned.

The PB footprint size is also minimized. This frees up PB space for other components around the DUT and/or a smaller PB. Additionally, the thermal head shroud and PB interfaces are displaced vertically from each other using the adapter, allowing for each to be independently optimized.

### BRIEF DESCRIPTION OF THE DRAWINGS

Various embodiments are described herein with reference to the following drawings. Certain aspects of the drawings are depicted in a simplified way for reason of clarity. Not all alternatives and options are shown in the drawings and, therefore, the invention is not limited in scope to the content of the drawings. In the drawings:

FIG. 1 is a perspective view of a thermal head adapter according to one embodiment of the invention;

FIG. 2 is a top view of a thermal head adapter of FIG. 1 placed over a DUT test socket;

FIG. 3 is a cross-sectional A-A view of the thermal head adapter and DUT test socket of FIG. 2 and its host PB;

FIG. 4 is a cross-sectional view of an alternative thermal head adapter and DUT test socket embodiment; and

FIG. 5 depicts a precision temperature forcing system (PTFS) with its thermal cap pressure sealed to the top of the DUT test socket and its shroud pressure sealed to the top of the thermal head adapter of FIG. 1 in the operating position.

### DETAILED DESCRIPTION

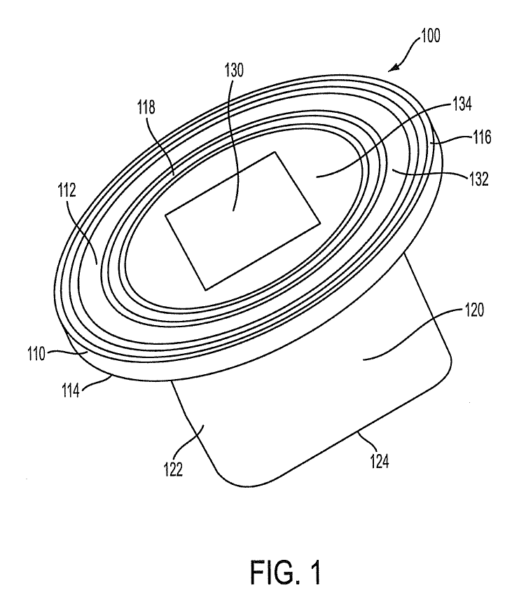

FIG. 1 depicts a perspective view of a thermal head adapter 100 according to one embodiment of the present invention. Thermal head adapter 100 is provided for use with a precision temperature forcing system (PTFS) for interfacing a printed board (PB) with a DUT or a DUT test socket to the thermal cap and shroud of the thermal head of the PTFS.

Thermal head adapter 100 comprises a first section 110 and a second section 120. First section 110 comprises an upper surface 112 and a lower surface 114. A shroud (not shown) of a PTFS is pressure sealed to upper surface 112. A first ridge 116 is formed along the perimeter of upper surface 112 of first section 110. If the perimeter of first section 110 is circular in shape, first ridge 116 may be circular in shape as well, as shown in FIG. 1. A second ridge 118 is formed on upper surface 112 at a substantially uniform distance from the first ridge 116. Second ridge 118 has a smaller perimeter than first ridge 116, as shown in FIG. 1. Thermal head adapter 100 also includes a cavity 130, which is the space between DUT test socket 190 and the inner wall of both first section 110 and second section 120.

First section 110 and second section 120 may be manufactured as a single piece. Alternatively, first section 110 and second section 120 may be manufactured as separate pieces, and may either be permanently or removably affixed to each other. First section 110 and second section 120 may be made from a molded plastic. The material used to manufacture first section 110 and second section 120 is preferably compatible with the temperature range of the precision temperature forcing system (e.g. −90° C. to +225° C.). The material used for first section 110 and second section 120 should at least be compatible with the temperature ranges used while testing the DUT, e.g. −55° C. to +125° C.

First ridge 116 and second ridge 118 may be molded out of the same piece of material as first section 110 and second section 120. First ridge 116 is at a height superior to upper surface 112. Second ridge 118 is at a height superior to upper surface 112. First ridge 116 and second ridge 118 may be the same height. Alternatively, first ridge 116 and second ridge 118 may be different heights.

Condensation from moist room air may form on the exterior walls of the shroud. This condensation may then fall down the exterior walls of the shroud and compile as a liquid on upper surface 112. A first region 132 bounded by first ridge 116, upper surface 112, and second ridge 118 is formed to contain the fallen liquid. Condensation that lands on upper surface 112 would fall within first region 132. When affixing the shroud to upper surface 112, the shroud may be placed at any location on upper surface 112 within first region 132. First ridge 116 and second ridge 118 should be a height sufficient to contain the condensation that falls on upper surface 112 from the shroud and direct it towards a drain 160 (not shown).

A second region 134 comprises the portion of upper surface 112 that is located between second ridge 118 and cavity 130.

Second section 120 comprises at least one sidewall 122 and a base 124. The perimeter of base 124 of second section 120 is less than the perimeter of first section 110. Base 124 is pressure leaded against the PB.

Cavity 130 is sized to accommodate a DUT or a DUT test socket. Cavity 130 runs through both first section 110 and second section 120. Cavity 130 of thermal head adapter 100 may be aligned with a DUT or a DUT test socket, wherein the test socket is already set up on the PB.

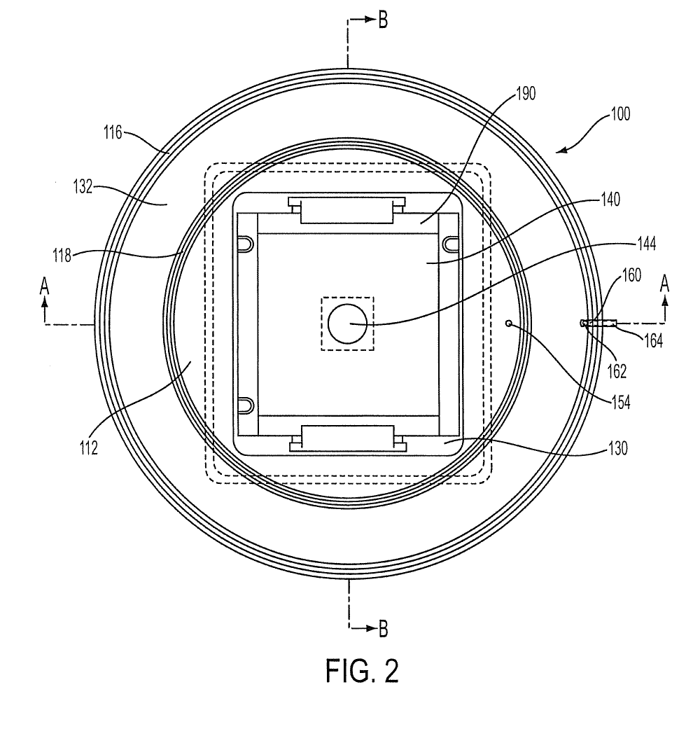

FIG. 2 is a top view of thermal head adapter 100 according to one embodiment of the invention. FIG. 2 shows the thermal head adapter 100 placed over a DUT test socket 190 mounted to a host PB 192. A thermal cap of the thermal head (not shown) will be pressure sealed to the top of DUT test socket 190 in operation. Because the top surface of DUT test socket 190 may not be perfectly flat, a test socket interface 140 may be placed on top of DUT test socket 190 to provide a smooth, flat surface for a good air seal with the bottom edge of the thermal cap of the thermal head. Test socket interface 140 may be a plate with a flat top surface 142 and a hole 144. Test socket interface 140 may be rectangular-shaped. Alternatively, test socket interface 140 may comprise other shapes as well. Hole 144 should align with the exposed portion of the DUT in DUT test socket 190 to allow for maximum airflow onto the DUT. The material used to manufacture test socket interface 140 is preferably compatible with the temperature range of the precision temperature forcing system (e.g. −90° C. to +225° C.). The material used for test socket interface 140 should at least be compatible with the temperature ranges used while testing the device under test, e.g. −55° C. to +125° C.

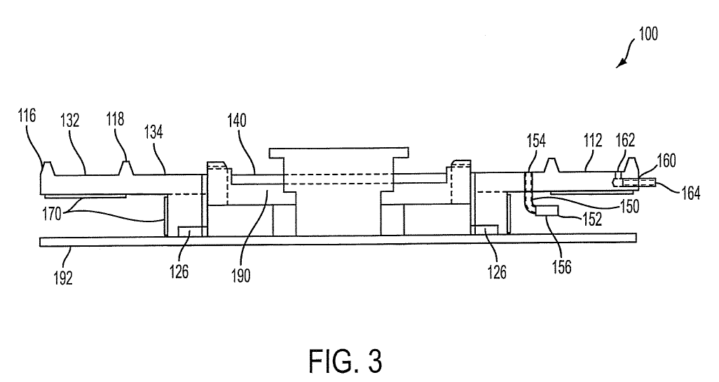

FIG. 3 is a cross-sectional view of section A-A of thermal head adapter 100 and a DUT test socket 190 mounted to host PB 192 from FIG. 2. In FIG. 3, the cross-section A-A illustrates the component parts of thermal head adapter 100 and how they interface with the DUT test socket 190 and host PB 192.

A foam gasket 126 may be affixed within a hollowed-out portion of base 124. Foam gasket 126 would allow for compression when thermal head adapter 100 is either manually or mechanically pressed down onto host PB 192, enabling a compression-seal of thermal head adapter 100 to the host PB 192.

In one aspect of the invention, the thermal management system may utilize dry nitrogen for forcing air temperature within the shroud closer to room temperature. For this situation, a port 150 extends from a port inlet 152 through a port outlet 154 on upper surface 112. Port outlet 154 is located within second region 134 on upper surface 112. Port 150 is provided for injecting dry nitrogen into the shroud area. Within the shroud area, the injected room temperature dry nitrogen mixes with the DUT exhaust air to bring shroud air closer to room temperature. A plug 156 may be inserted into port 150 when port 150 is not in use. Alternatively, port 150 may be located in second section 120.

A drain 160 extends from a drain inlet 162 on upper surface 112 through a drain outlet 164. Drain inlet 162 of drain 160 is located within the first region 132 on upper surface 112. Condensation forms on the outside walls of the shroud and falls to first region 132 on upper surface 112, and flows through drain inlet 162, exiting through drain outlet 164 into an appropriate device, such as a tube or a container. Drain 160 allows for condensation to be properly removed from thermal head adapter 100.

A plurality of heaters 170 may be attached to lower surface 114 of first section 110 or a sidewall of the at least one sidewall 122 of second section 120. FIG. 3 shows heaters 170 on both lower surface 114 and sidewall 122. Alternatively, a single heater may be used in some embodiments. The plurality of heaters 170 may be flexible foil heaters. The plurality of heaters 170 may be bonded to the surfaces of thermal head adapter 100. The plurality of heaters 170 may have integral temperature sensors that are bonded to the exterior sidewall 122 of the base second section 120 near the PB interface and to the exterior lower surface 114 of first section 110 opposite the thermal head footprint. The plurality of heaters 170 would provide a means of keeping the outside surface of thermal head adapter above the dew point of room air to prevent condensation and icing. The plurality of heaters 170 may be Minco Flexible Thermofoil™ heaters.

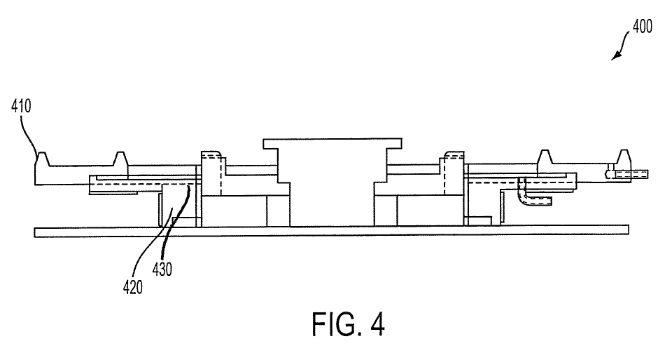

FIG. 4 is a cross-sectional view depicting an alternative embodiment of thermal head adapter 400. In this embodiment, an upper shroud interface 410 and a lower PB interface 420 are separate pieces that are removably affixed to one another at a common circular interface 430. The common circular interface has a gasket seal to affix upper shroud interface 410 to lower PB interface 420. Thus, various sized lower PB interfaces are interchangeable for use with the same upper shroud interface 410. Various sized upper shroud interfaces may be interchangeable for use with the same lower PB interface 420. For example, if the testing situation requires a smaller lower PB interface, a smaller sized PB interface may be selected from a range of various sized PB interfaces and sealed onto upper shroud interface 410. If a subsequent testing procedure requires a larger sized lower PB interface 420, the previous lower PB interface may be removed and a larger sized lower PB interface 420 may be sealed onto upper shroud interface 410. This embodiment allows for various combinations of upper shroud interfaces 410 and lower PB interfaces 420 to be assembled to meet various thermal testing applications.

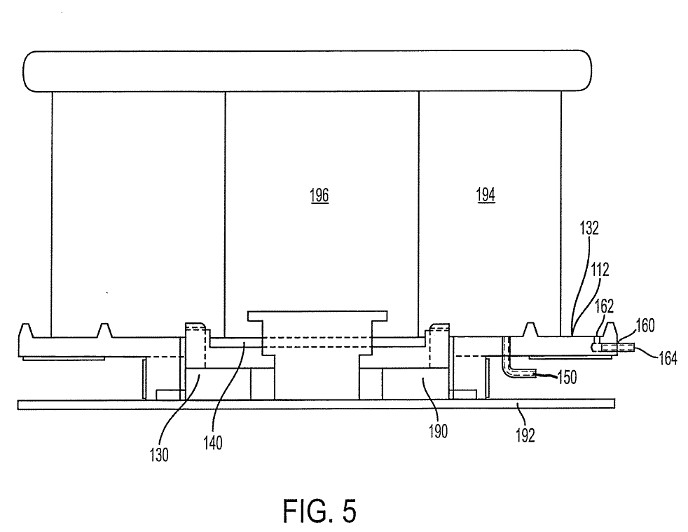

In operation, a DUT test socket 190 is affixed (e.g. soldered) to PB 192, as shown in FIG. 5. Cavity 130 of thermal head adapter 100 is then aligned with DUT test socket 190 so that when thermal head adapter 100 is placed over the DUT test socket 190 and onto PB 192, the DUT test socket 190 rests within cavity 130. Thermal head adapter 100 may be pressed down onto the PB 192, compressing foam gasket 126 within base 124 so that base 124 is pressure sealed to the PB 192. A shroud 194 of a thermal head is placed onto upper surface 112 within first region 132. A thermal cap 196 of a thermal head is placed onto test socket interface 140.

Once the DUT is in position in the DUT test socket 190 and is ready for testing, forced air from the thermal head flows through hole 144 and/or cavity 130, and onto the exposed portion of the DUT. The majority of the forced air exits the vent holes of the thermal cap. Some of the forced air flows through the test socket and across the DUT, the air then moves out the sides and bottom of the test socket, exiting the test socket and flowing up into the shroud area. The air eventually flows out of the shroud through thermal head vents (not shown). The air that enters the shroud may be cool or cold air. To warm this cold air, room temperature dry nitrogen gas may be injected via port 150 into the shroud. The room temperature dry nitrogen gas mixes with the cold thermal cap and DUT test socket 190 exhaust air to reduce the temperature differential across the shroud walls and condensation and icing on its exterior walls from moist room air.

If moist room air against the outside walls of the shroud is cooled to its dewpoint, condensation may form on the outside walls of the shroud. When this condensation falls down the outside wall of the shroud, it will land as a liquid in first region 132 on upper surface 112 of thermal head adapter 100. The liquid then enters drain inlet 162 and flows through drain 160 to exit through drain outlet 164. The capturing and draining of the condensed liquid keeps moisture from entering the DUT test socket 190 and damaging the device under test (DUT), its host PB 192 or other components or test equipment.

Once the testing of the DUT is finished, thermal cap 196 and shroud 194 of the thermal head are mechanically lifted off the test socket interface 140, and upper surface 112 of first section 110.

Thermal head adapter 100 vertically displaces the shroud and the PB interfaces so that each can be independently optimized. Because of the thermal head adapter's design, the PB footprint size can be minimized. Minimization of the PB footprint size frees up space for other components to be placed around the DUT test socket 190.

Variations and modifications of the present invention will be obvious to those skilled in the art and it is intended to cover in the appended claims all such modifications and equivalents. The entire disclosures of all references, applications, patents, and publications cited above, are hereby incorporated by reference.

We claim:

1. An adapter for a thermal head, the adapter comprising:
a first section having upper and lower planar surfaces, wherein a thermal head can be secured onto and removed from the upper planar surface; and
a second section having a base and at least one upstanding outer wall;
wherein the first section has a larger perimeter than the second section and wherein a cavity runs through both the first section and the second section.

2. The adapter of claim 1, wherein the first section and the second section are manufactured as a single piece.

3. The adapter of claim 1, wherein the base of the second section is removably attachable to a printed board.

4. The adapter of claim 3, wherein at least a portion of the base of the second section comprises a compressible foam material.

5. The adapter of claim 4, wherein the base of the second section is secured to the printed board by compression.

6. The adapter of claim 1, further comprising a first ridge along a first perimeter of the upper planar surface.

7. The adapter of claim 6, further comprising a second ridge along a second perimeter of the upper planar surface, wherein the second perimeter is less than the first perimeter.

8. The adapter of claim 7, further comprising a drain that lies between the first ridge and the second ridge and that begins at the upper surface and ends outside a surface of the first section and a nitrogen port that lies between the cavity and the second ridge and that extends from the upper surface to at least the lower surface or the upstanding outer wall.

9. The adapter of claim 7, further comprising at least one heater attached to an exterior surface of the adapter.

10. The adapter of claim 1, wherein the temperature-controlled forced air originates from a precision temperature forcing system.

11. The adapter of claim 10, wherein a thermal cap from the precision temperature forcing system is attached to a device under test or a test socket, to deliver temperature-controlled forced air onto the device under test.

12. An adapter for a thermal head, the adapter comprising:
an upper surface with a first perimeter; and
a lower surface with a second perimeter;
wherein the first perimeter is greater than the second perimeter and wherein a thermal head can be removably attached to the upper surface.

13. A removable adapter for testing a device in a test system having a thermal head, the adapter comprising:
a first section having top and bottom planar surfaces and at least one ridge along a perimeter of the first planar surface; wherein a thermal head can be secured to and removed from the top planar surface;
a second section having a base, wherein the second section is removable from the first section;
wherein a cavity runs through both the first section and the second section and wherein the top and bottom planar surfaces of the first section comprise a different perimeter than the base of the second section.

14. The removable adapter of claim 13, wherein the base of the second section can be secured to and removed from a printed board.

15. The removable adapter of claim 14, wherein at least a portion of the base of the second section comprises a compressible foam material.

16. The removable adapter of claim 15, wherein the base of the second section is secured to the printed board by compression.

17. The removable adapter of claim 13, further comprising a test socket interface with a flat planar upper surface, wherein a thermal cap of a thermal head is sealed onto the flat planar upper surface.

18. The removable adapter of claim 13, further comprising at least one heater attached to the second section.

19. The removable adapter of claim 13, further comprising at least one heater attached to the bottom planar surface of the first section.

20. The removable adapter of claim 19, wherein the two ridges comprise a first ridge and a second ridge and wherein the first ridge spans a first circumference on the top planar surface and the second ridge spans a second circumference on the top planar surface that is smaller than the first circumference.
